(19) United States
(12) Patent Application Publication
(10) Pub. No.: US 2026/0057936 A1
(43) Pub. Date: Feb. 26, 2026

(54) MEMORY DEVICES

(71) Applicant: Samsung Electronics Co., Ltd., Suwon-si (KR)

(72) Inventors: Intak JEON, Suwon-si (KR); Seonyong KIM, Suwon-si (KR); Hanjin LIM, Suwon-si (KR); Jayun CHOI, Suwon-si (KR)

(73) Assignee: Samsung Electronics Co., Ltd., Suwon-si (KR)

(21) Appl. No.: 19/294,449

(22) Filed: Aug. 8, 2025

(30) Foreign Application Priority Data
Aug. 26, 2024 (KR) 10-2024-0114491

(51) Int. Cl. G11C 14/00; H10B 12/00; H10B 53/10; H10B 53/20; H10B 53/30; H10B 53/40

(52) U.S. Cl. CPC G11C 14/0027; H10B 12/50; H10B 53/10; H10B 53/20; H10B 53/30; H10B 53/40

(57) ABSTRACT

Provided is a memory device including a first transistor disposed on a first vertical level on a substrate, a common electrode electrically connected to the first transistor and extending in a first direction perpendicular to an upper surface of the substrate, a first memory unit disposed on a second vertical level higher than the first vertical level on the substrate and electrically connected to the common electrode, and a second memory unit disposed on a third vertical level higher than the first vertical level and different from the second vertical level on the substrate and electrically connected to the common electrode, wherein the first memory unit includes a first dielectric layer including a dielectric material or a paraelectric material, and the second memory unit includes a second dielectric layer including a ferroelectric material or an antiferroelectric material.

### CROSS-REFERENCE TO RELATED APPLICATION

This application is based on and claims priority under 35 U.S. C. § 119 to Korean Patent Application No. 10-2024-0114491, filed on Aug. 26, 2024 in the Korean Intellectual Property Office, the disclosure of which is incorporated by reference herein in its entirety.

### BACKGROUND

The inventive concept relates to a memory device, and more particularly, to a hybrid-type memory device and a method of manufacturing the memory device.

Memory devices are used in various electronic components. As applications (e.g., artificial intelligence, Internet of Things, etc.) of memory devices have become diversified, higher integration and multi-functionalization of memory devices have been desired. General dynamic random access memory (DRAM) devices have structures in which one transistor is connected to one capacitor. General DRAM devices have limitations in integration and technical difficulties in low-power operation and may be difficult to be applied to various memory devices such as an embedded chip or a neuromorphic chip.

### SUMMARY

The present disclosure provides hybrid-type memory devices including a volatile memory device and a non-volatile memory device.

According to an example embodiments of the inventive concepts, a memory device includes a first transistor on a first vertical level on a substrate, a common electrode electrically connected to the first transistor, the common electrode extending in a first direction perpendicular to an upper surface of the substrate, a first memory unit on a second vertical level higher than the first vertical level on the substrate, the first memory unit electrically connected to the common electrode, and a second memory unit on a third vertical level higher than the first vertical level and different from the second vertical level on the substrate, the second memory unit electrically connected to the common electrode, wherein the first memory unit includes a first dielectric layer including a dielectric material or a paraelectric material, and the second memory unit includes a second dielectric layer including a ferroelectric material or an antiferroelectric material.

According to an example embodiments of the inventive concepts, a memory device includes a first transistor and a second transistor on a substrate, a memory string electrically connected to the first transistor and the second transistor, the memory string being in a first direction perpendicular to an upper surface of the substrate, the memory string including a plurality of first memory units and a plurality of second memory units that are connected to each other in series, and a common electrode extending in the first direction, the common electrodes electrically connected to the first transistor and the second transistor, wherein the plurality of first memory units include volatile memory and the plurality of second memory units include non-volatile memory.

According to an example embodiments of the inventive concepts, a memory device includes a plurality of first transistors on a first vertical level on a substrate, a plurality of common electrodes electrically connected to the plurality of first transistors, respectively, the plurality of common electrodes extending in a first direction perpendicular to an upper surface of the substrate, a first plate electrode on a second vertical level higher than the first vertical level on the substrate, the first plate electrode surrounding the plurality of common electrodes, a plurality of first dielectric layers between the first plate electrode and the plurality of common electrodes, the plurality of first dielectric layers surrounding the plurality of common electrodes, respectively, a second plate electrode on a third vertical level higher than the first vertical level and different from the second vertical level on the substrate, the second plate electrode surrounding the plurality of common electrodes, and a plurality of second dielectric layers between the first plate electrode and the plurality of common electrodes, the plurality of second dielectric layers surrounding the plurality of common electrodes, respectively, wherein the plurality of first dielectric layers include a dielectric material or a paraelectric material, and the plurality of second dielectric layers include a ferroelectric material or an antiferroelectric material.

### BRIEF DESCRIPTION OF THE DRAWINGS

Example embodiments will be more clearly understood from the following detailed description taken in conjunction with the accompanying drawings in which:

FIG. 1 is a circuit diagram of a memory device according to some example embodiments;

FIG. 2 is a circuit diagram of a memory device according to some example embodiments;

FIG. 3 is a circuit diagram of a memory device according to some example embodiments;

FIG. 4 is a circuit diagram of a memory device according to some example embodiments;

FIG. 5 is a schematic perspective view of a memory device according to some example embodiments;

FIG. 6 is a circuit diagram corresponding to the memory device of FIG. 5;

FIG. 7 is a schematic layout of an arrangement of the memory device of FIG. 5;

FIG. 8 is a cross-sectional view of the memory device taken along line A-A′ of FIG. 7;

FIG. 9 is a horizontal cross-sectional view of the memory device of FIG. 8 on a second vertical level;

FIG. 10 is a horizontal cross-sectional view of the memory device of FIG. 8 on a third vertical level;

FIG. 11 is a cross-sectional view of a memory device according to some example embodiments;

FIG. 12 is a horizontal cross-sectional view of the memory device of FIG. 11 on a second vertical level;

FIG. 13 is a horizontal cross-sectional view of the memory device of FIG. 11 on a third vertical level;

FIG. 14 is a cross-sectional view of a memory device according to some example embodiments;

FIG. 15 is a circuit diagram corresponding to the memory device of FIG. 14;

FIG. 16 is a cross-sectional view of a memory device according to some example embodiments; and

FIG. 17 is a cross-sectional view of a memory device according to some example embodiments.

### DETAILED DESCRIPTION

Hereinafter, some example embodiments will be described in detail with reference to the accompanying drawings.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

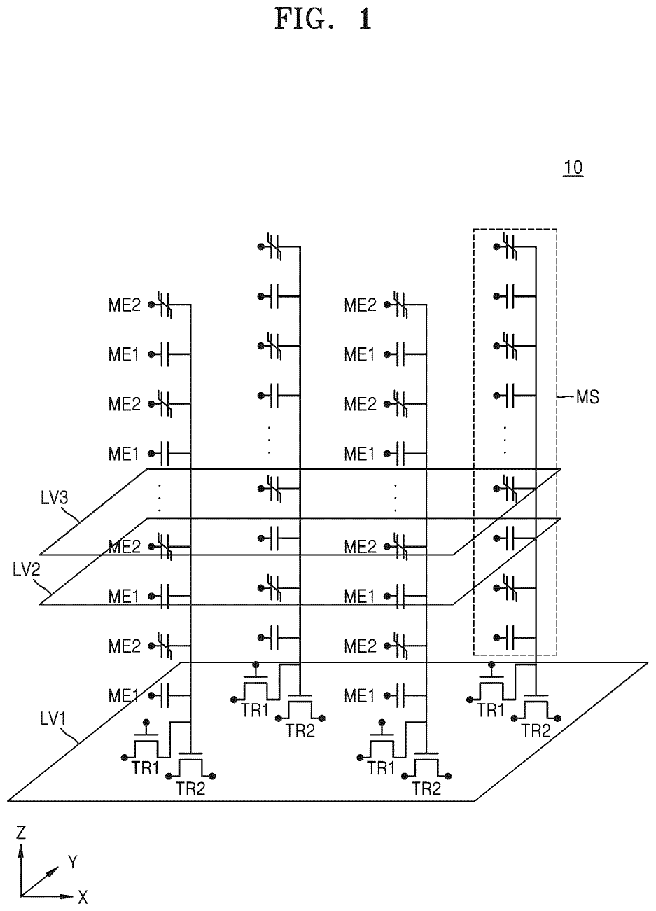

FIG. 1 is a circuit diagram of a memory device 10 according to some example embodiments.

Referring to FIG. 1, the memory device 10 may include a plurality of memory strings MS and each memory string MS may extend in a vertical direction Z. Each memory string MS may include a plurality of first memory units ME1 and a plurality of second memory units ME2 and, in some example embodiments, as illustrated in FIG. 1, the plurality of first memory units ME1 and the plurality of second memory units ME2 may be alternately disposed in the vertical direction Z.

In some example embodiments, the plurality of first memory units ME1 may include a metal-insulator-metal (MIM) capacitor-type volatile memory unit. In some example embodiments, the plurality of first memory units ME1 may be a capacitor type memory based on a dielectric material. In some example embodiments, the plurality of first memory units ME1 may be a capacitor type memory based on a paraelectric material. The expression, “dielectric material” or “paraelectric material” may be understood as materials in which polarization appears when a voltage is applied to the dielectric material or the paraelectric material and in which polarization disappears when a voltage is not applied thereto.

In some example embodiments, the plurality of second memory units ME2 may include a non-volatile memory unit having an MIM laminate structure. In some example embodiments, the plurality of second memory units ME2 may include a memory unit based on a ferroelectric material. In some example embodiments, the plurality of second memory units ME2 may include a memory unit based on an antiferroelectric material. The expression, “ferroelectric material” or “antiferroelectric material” may be understood as a material showing voltage-current hysteresis characteristics when a voltage is applied to the ferroelectric material or the antiferroelectric material.

In some example embodiments, the voltage-current hysteresis characteristics may refer to characteristics in which a hysteresis curve may be observed in the voltage-current curve (or electric field-polarization curve) through spontaneous polarization. For example, polarization may occur when an electric dipole moment is arranged inside a material when a desired (or alternatively, predetermined) voltage (e.g., a write voltage) is applied to the ferroelectric material or the antiferroelectric material and, even if a voltage of 0 V is applied to the ferroelectric material or the antiferroelectric material, polarization may be left in the material. The voltage-current hysteresis characteristics or the electric field-polarization hysteresis characteristics may be used for the material to be used as a non-volatile memory device.

In some example embodiments, the memory device 10 may include driving transistors electrically connected to an end of each of the memory strings MS. In some example embodiments, the driving transistors may include a first transistor TR1 and a second transistor TR2 electrically connected to an end of each of the memory strings MS.

In some example embodiments, each memory string MS may be connected to a drain electrode of the first transistor TR1 and a gate electrode of the second transistor TR2 may be connected to the drain electrode of the first transistor TR1. For example, the plurality of first memory units ME1 and the plurality of second memory units ME2 may be connected in series to the drain electrode of the first transistor TR1 and the gate electrode of the second transistor TR2 may be connected to the drain electrode of the first transistor TR1. In some example embodiments, the first transistor TR1 may be a control transistor configured to control each memory string MS and the second transistor TR2 may be a sensing transistor configured to sense each memory string MS.

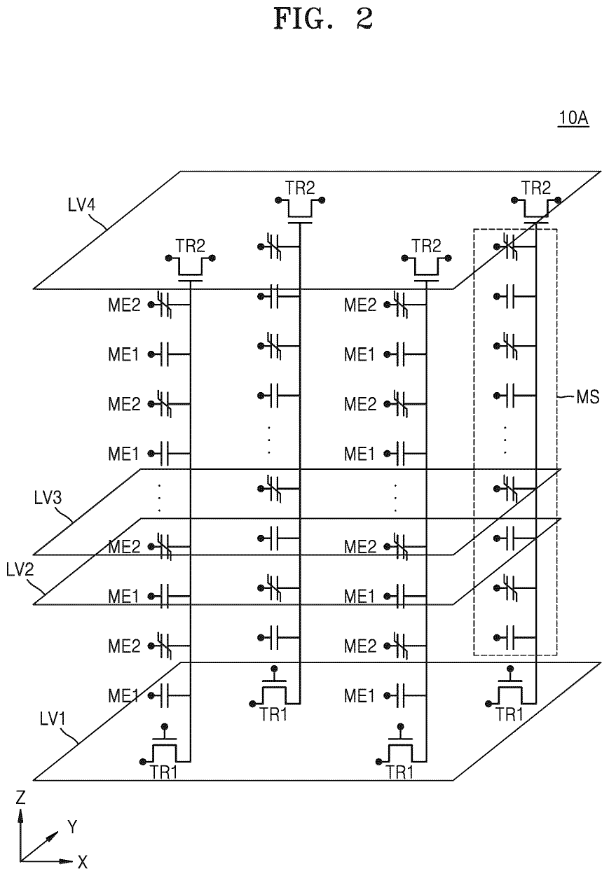

In some example embodiments, as shown in FIG. 1, the first transistor TR1 and the second transistor TR2 may be disposed on a first vertical level LV1. For example, the first transistor TR1 and the second transistor TR2 may be disposed on a plane on a substrate 110 (refer to FIG. 2) and the first transistor TR1 and the second transistor TR2 may be referred to as a pair of driving transistors. The plurality of driving transistor pairs (each pair including the first transistor TR1 and the second transistor TR2) may be disposed in a matrix form on the substrate 110. For example, among the plurality of driving transistor pairs, m driving transistor pairs may be disposed in a first horizontal direction (the X direction) and n driving transistor pairs may be disposed in a second horizontal direction (the Y direction) such that the driving transistor pairs form m×n arrays on the first vertical level LV1.

The plurality of memory strings MS may form m×n arrays in a planar location corresponding to the plurality of driving transistor pairs. For example, each memory string MS may be disposed in a location vertically overlapping a pair of corresponding driving transistors (e.g., corresponding first transistor TR1 and second transistor TR2) and may extend in the vertical direction (the Z direction).

In some example embodiments, the plurality of first memory units ME1 disposed on a second vertical level LV2 may include a volatile memory unit and may form m×n arrays in a plan view. The plurality of second memory units ME2 disposed on a third vertical level LV3 may include a non-volatile memory unit and may form m×n arrays in a plan view.

In some example embodiments, each memory string MS and driving transistors driving the memory string MS may form a unit element structure in which two types of transistors (e.g., i volatile memory units (the first memory unit ME1 or a capacitor) and j non-volatile memory units (the second memory unit ME2 or a ferroelectric memory unit) are electrically connected to each other). Such a structure may be referred to as a 2T-iC-jF structure. For example, i+j may refer to the total number of laminated memory units and i+j may be in between about 10 to about 2000. However, example embodiments are not limited thereto.

In some example embodiments, the electronic device includes the memory device 10 in which memory strings MS each including a volatile memory unit and a non-volatile memory unit are provided, the memory device 10 may operate to store and read data as a volatile memory device or a non-volatile memory device in various memory devices such as an embedded chip or a neuromorphic chip. Therefore, the memory device 10 may have improved operational flexibility.

FIG. 2 is a circuit diagram of a memory device 10a according to some example embodiments.

Referring to FIG. 2, the first transistor TR1 may be disposed on the first vertical level LV1 and the second transistor TR2 may be disposed on a fourth vertical level LV2 higher than the first vertical level LV1. The plurality of memory strings MS may extend in the vertical direction (the Z direction) between the first transistor TR1 and the second transistor TR2.

In some example embodiments, a bottom end of each memory string MS may be connected to the drain electrode of the first transistor TR1 and the gate electrode of the second transistor TR2 may be connected to a top end of each memory string MS. In some example embodiments, the first transistor TR1 may be a control transistor configured to control each memory string MS and the second transistor TR2 may be a sensing transistor configured to sense each memory string MS.

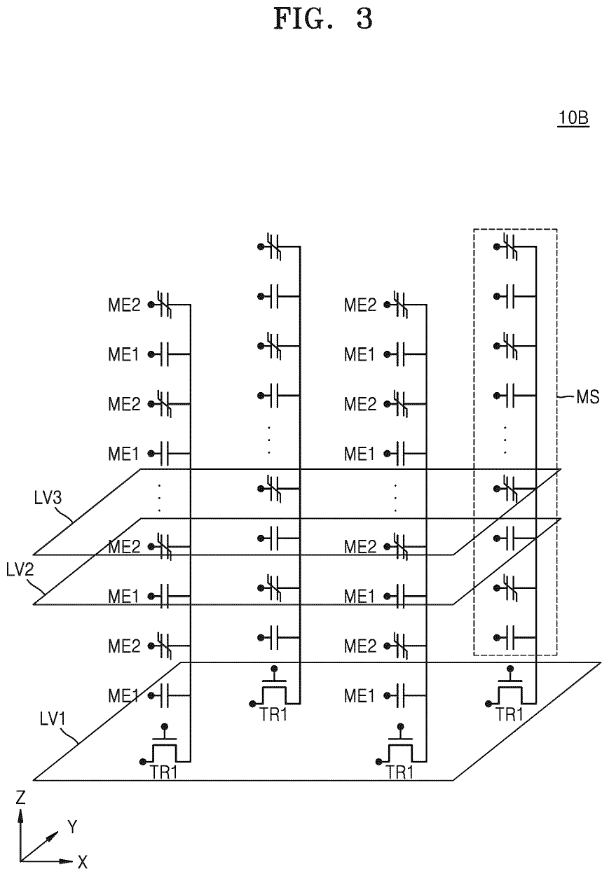

FIG. 3 is a circuit diagram of a memory device 10B according to some embodiments.

Referring to FIG. 3, the first transistor TR1 may be disposed on the first vertical level LV1 and the plurality of memory strings MS may be connected to the drain electrode of the first transistor TR1 and extend in the vertical direction (the Z direction). In some example embodiments, the first transistor TR1 may be a control transistor configured to control each memory string MS.

In the example embodiments according to FIG. 3, the second transistor described with reference to FIGS. 1 and 2 may be omitted.

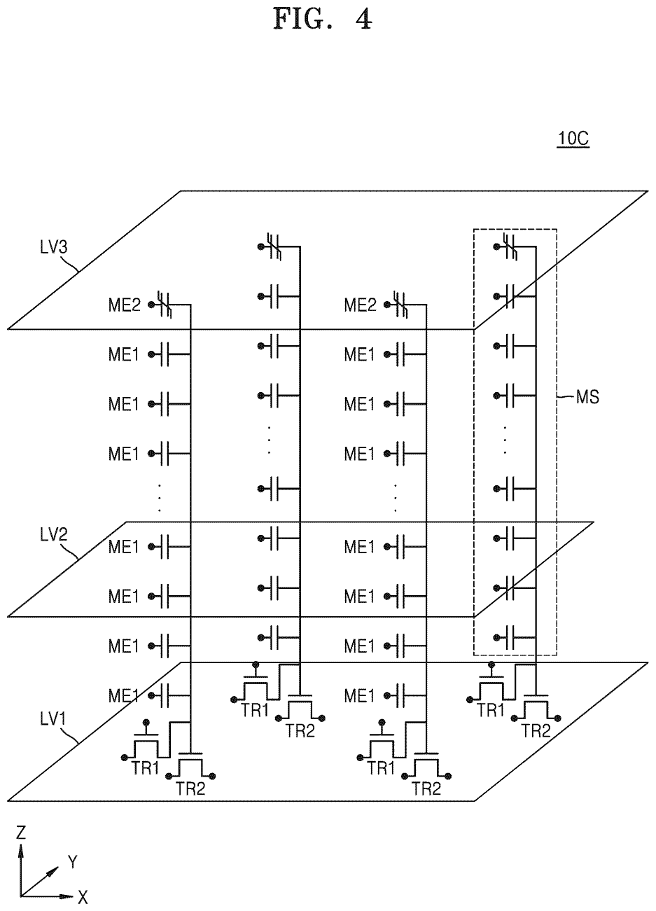

FIG. 4 is a circuit diagram of a memory device 10C according to some example embodiments.

Referring to FIG. 4, the plurality of memory strings MS may include at least one second memory unit ME2 disposed on the top of each memory string MS and the plurality of first memory units ME1 disposed on a vertical level lower than the at least one second memory unit ME2.

In some example embodiments, the at least one second memory unit ME2 may include a non-volatile memory unit based on a ferroelectric material or an antiferroelectric material and the plurality of first memory units ME1 may include a volatile memory unit based on a dielectric material or a paraelectric material.

In some example embodiments, the number of at least one second memory units ME2 included in each memory string MS may be different from the number of the plurality of first memory units ME1 included in a corresponding memory string MS. The number of at least one second memory units ME2 included in each memory string MS and the number of the plurality of first memory units ME1 included in a corresponding memory string MS may differ according to an application of an electronic device to which the memory device 10C may be applied.

FIG. 4 illustrates that at least one second memory unit ME2 is disposed on the top of each memory string MS and the plurality of first memory units ME1 are disposed on a vertical level lower than the at least one second memory unit ME2. However, in some example embodiments, at least one second memory unit ME2 may be disposed on the bottom of each memory string MS and the plurality of first memory units ME1 may be disposed on a vertical level higher than the at least one second memory unit ME2.

In some example embodiments, at least one second memory unit ME2 may be disposed on the bottom end of each memory string MS, at least one second memory unit ME2 may be disposed on the top end of each memory string MS, and a plurality of first memory units ME1 may be disposed on the middle of each memory string MS (e.g., between the at least one second memory unit ME2 and the at least one other second memory unit ME2).

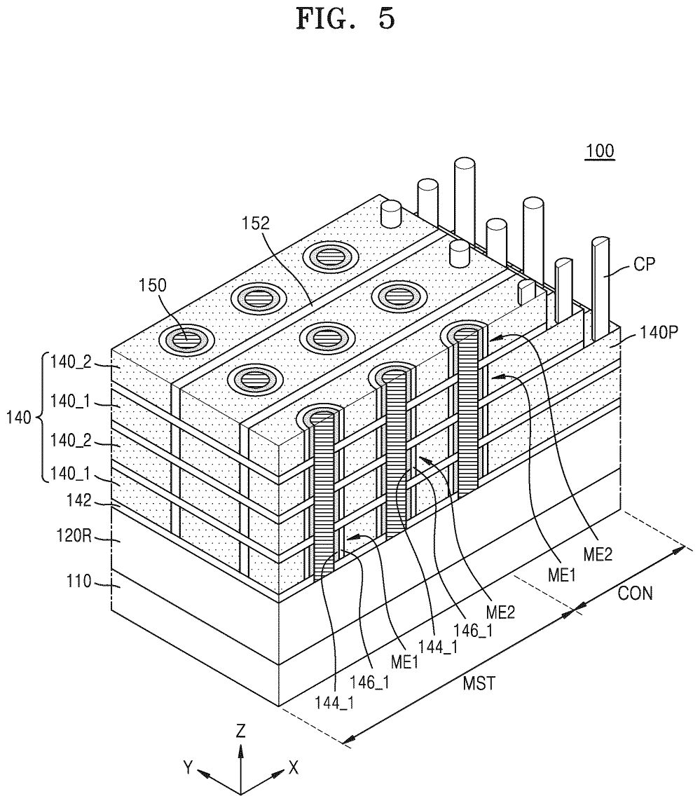

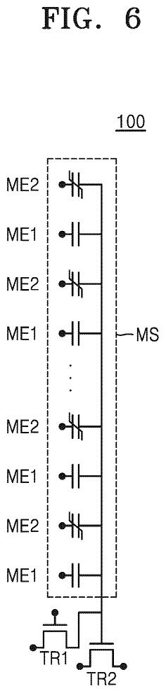

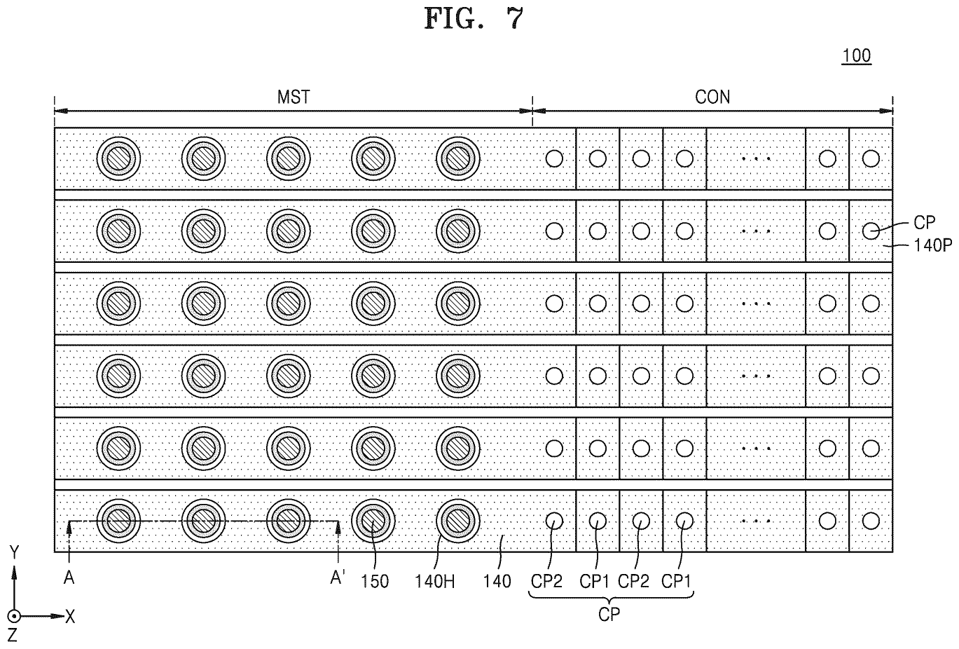

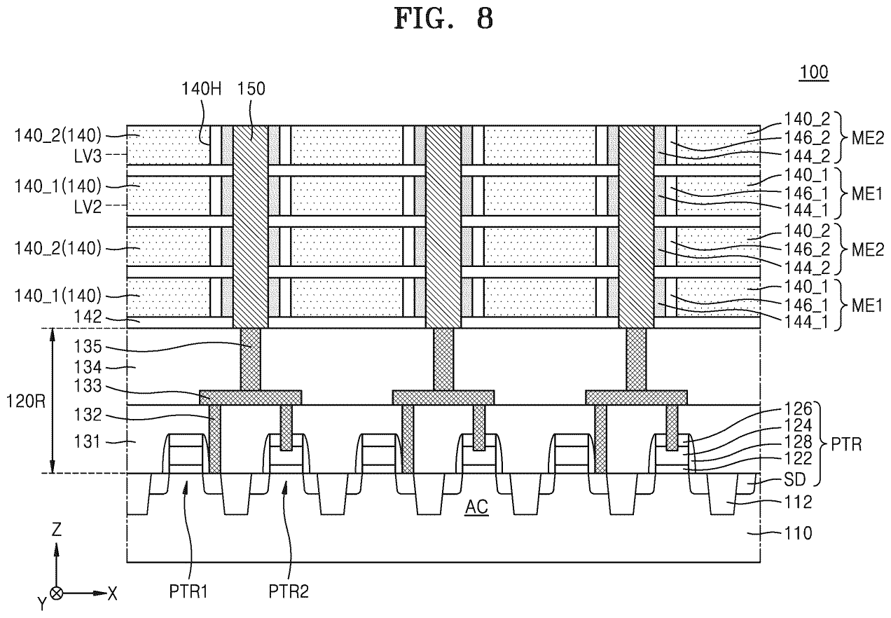

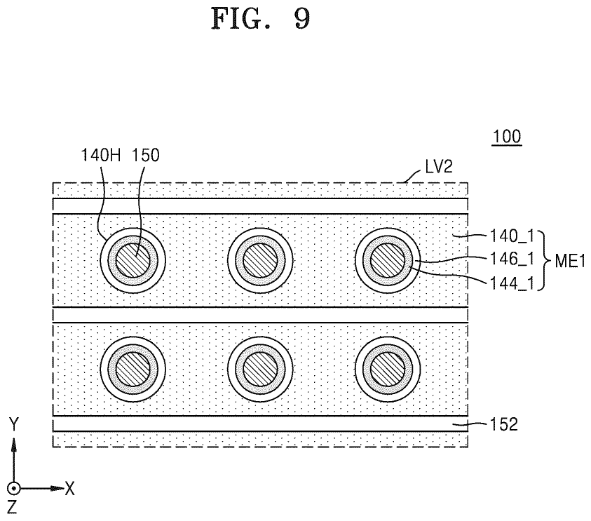

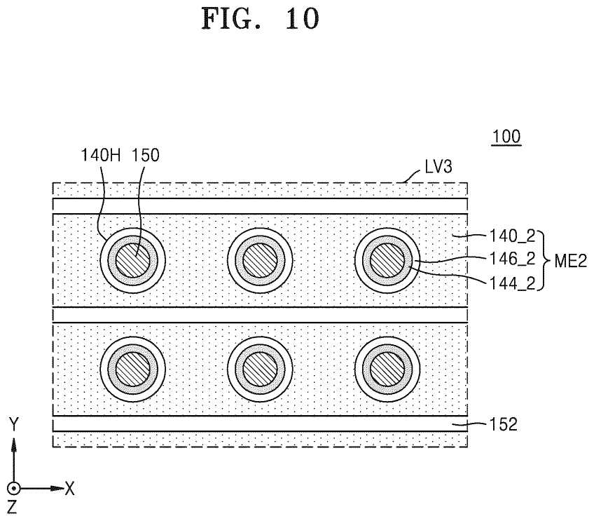

FIG. 5 is a schematic perspective view of a memory device 100 according to some example embodiments. FIG. 6 is a circuit diagram corresponding to the memory device of FIG. 5. FIG. 7 is a schematic layout of an arrangement of the memory device of FIG. 5. FIG. 8 is a cross-sectional view of the memory device taken along line A-A of FIG. 7. FIG. 9 is a horizontal cross-sectional view of the memory device of FIG. 8 on the second vertical level LV2, and FIG. 10 is a horizontal cross-sectional view of the memory device of FIG. 8 on the third vertical level LV3.

Referring to FIGS. 5 to 10, the memory device 100 may include a transistor region 120R disposed on the substrate 110 and a memory cell stack MST on the transistor region 120R. The transistor region 120R may be a region in which the first transistor TR1 and the second transistor TR2 of FIG. 6 are arranged. The memory cell stack MST may be an area in which the memory string MS of FIG. 6 is disposed.

An active region AC may be defined by an element isolation layer 112 in the substrate 110 and a driving transistor PTR may be disposed on the active region AC of the substrate 110. In some example embodiments, the driving transistor PTR may include a planar transistor. The driving transistor PTR may include a gate insulating layer 122, a gate electrode 124, and a gate capping layer 126, which are sequentially disposed on the substrate 110. In some example embodiments, the driving transistor PTR may further include a spacer 128 disposed on side walls of the gate insulating layer 122, the gate electrode 124, and the gate capping layer 126. In some example embodiments, the driving transistor PTR may further include a source/drain region SD disposed on both sides of the gate electrode 124 and inside the substrate 110.

A first insulating layer 131 covering the driving transistor PTR, a first contact 132 penetrating the first insulating layer 131 and connected to the driving transistor PTR, a wiring layer 133 disposed on the first insulating layer 131 and electrically connected to the first contact 132, a second insulating layer 134 covering the wiring layer 133 on the first insulating layer 131, and a second contact 135 penetrating the second insulating layer 134 and electrically connected to the wiring layer 133 may further be disposed on the substrate 110.

In some example embodiments, the driving transistor PTR may include a first transistor PTR1 and a second transistor PTR2 that are adjacently disposed on the substrate 110 and the first transistor PTR1 and the second transistor PTR2 may correspond to the first transistor TR1 and the second transistor TR2 shown in FIG. 6. For example, the source/drain region SD of the first transistor PTR1 may be electrically connected to the gate electrode 124 of the second transistor PTR2 through the first contact 132 and the wiring layer 133. In some example embodiments, the first transistor PTR1 may include a control transistor to control each memory string MS and the second transistor PTR2 may include a sensing transistor to sense each memory string MS.

In some example embodiments, the driving transistor PTR may be implemented as a transistor having a type other than the planar transistor shown in FIG. 8. In some example embodiments, the driving transistor PTR may include a vertical channel transistor including a semiconductor channel extending in the vertical direction. In some example embodiments, the driving transistor PTR may include a fin field effect transistor (FinFET) element including a fin-type active region. In some example embodiments, the driving transistor PTR may include a buried channel array transistor including a channel recessed into the substrate 110. In some example embodiments, the driving transistor PTR may include a multi bridge channel transistor including a plurality of nanosheets apart from each other in the vertical direction on the substrate 110. In some example embodiments, the driving transistor PTR may include a gate-all-around type transistor or a forksheet transistor.

In some example embodiments, the memory cell stack MST may be disposed on a vertical level higher than the transistor region 120R. The memory cell stack MST may include a plurality of plate electrodes 140 laminated in the vertical direction (the Z direction). A stack insulating layer 142 may be disposed between two adjacent plate electrodes 140. For example, the plurality of plate electrodes 140 and the plurality of stack insulating layers 142 may be alternately disposed on the second insulating layer 134.

In some example embodiments, the plurality of plate electrodes 140 may include at least one of Si, SiGe, Ti, TiN, Ta, TaN, W, WN, TiSiN, WSiN, Ru, Mo, or MoN. The plurality of stack insulating layers 142 may include at least one of silicon oxide, silicon nitride, or silicon oxynitride.

In some example embodiments, the plurality of plate electrodes 140 may correspond to first storage node electrodes of the plurality of first memory units ME1 and first storage node electrodes of the plurality of second memory units ME2 constituting the memory string MS. In some example embodiments, the plurality of plate electrodes 140 may include first plate electrodes 140_1 and second plate electrodes 140_2 alternately disposed in the vertical direction (the Z direction). The first plate electrode 140_1 may be the first storage node electrode of the first memory unit ME1, and the second plate electrode 140_2 may be the first storage node electrode of the second memory unit ME2.

In some example embodiments, each of the plurality of plate electrodes 140 may include an opening 140H penetrating the plurality of plate electrodes 140. In some example embodiments, a plurality of openings 140H penetrating one plate electrode 140 may be disposed apart from each other in the first horizontal direction (the X direction). In addition, the plurality of openings 140H penetrating one plate electrode 140 may vertically overlap a plurality of openings 140H penetrating another plate electrode 140 disposed below the plate electrode 140.

A common electrode 150 extending in the vertical direction Z may be disposed in each of the plurality of openings 140H. In some example embodiments, the common electrode 150 may have a pillar shape and extend in the vertical direction (the Z direction) through the memory cell stack MST. The common electrode 150 may extend to a transistor region 120R through the plurality of plate electrodes 140 and the plurality of stack insulating layers 142, and a bottom surface of the common electrode 150 may contact a top surface of the second contact 135.

In some example embodiments, the common electrode 150 may have a circular horizontal cross-section. In some example embodiments, the common electrode 150 may have other horizontal cross-sectional shapes such as an oval, quadrangle, rectangle, hexagon, rhombus, etc. In some example embodiments, the common electrode 150 may include at least one of Si, SiGe, Ti, TiN, Ta, TaN, W, WN, TiSiN, WSiN, Ru, Mo, or MoN.

In some example embodiments, a first electrode 144_1 and a first dielectric layer 146_1 surrounding a side wall of the common electrode 150 may be disposed in each opening 140H of the plurality of first plate electrodes 140_1. In some example embodiments, the first electrode 144_1 and the first dielectric layer 146_1 may each have an annular form surrounding the common electrode 150. The first electrode 144_1 and the first dielectric layer 146_1 may be disposed between each of the plurality of first plate electrodes 140_1 and the common electrode 150.

In some example embodiments, a plurality of first electrodes 144_1 may be apart from each other in the vertical direction (the Z direction) on a side wall of the common electrode 150 extending in the vertical direction (the Z direction), and the plurality of first dielectric layers 146_1 may be apart from each other in the vertical direction (the Z direction) on a side wall of each of the plurality of first electrodes 144_1. As illustrated in FIG. 8, upper surfaces of the first plate electrode 140_1, the first dielectric layer 146_1, and the first electrode 144_1 may be arranged on the same plane, and bottom surfaces of the first plate electrode 140_1, the first dielectric layer 146_1, and the first electrode 144_1 may be arranged on the same plane.

In some example embodiments, the stack insulating layer 142 may be disposed on an upper surface and a bottom surface of each of the plurality of first electrodes 144_1, and the stack insulating layer 142 may be disposed on an upper surface and a bottom surface of each of the plurality of first dielectric layers 146_1.

In some example embodiments, the first electrode 144_1 may include at least one of Si, SiGe, Ti, TiN, Ta, TaN, W, WN, TiSiN, WSiN, Ru, Mo, or MoN. In some example embodiments, the first dielectric layer 146_1 may include a dielectric material or a paraelectric material. In some example embodiments, the first dielectric layer 146_1 may include zirconium oxide, hafnium oxide, titanium oxide, strontium titanium oxide, hafnium zirconium oxide, niobium oxide, tantalum oxide, aluminum oxide, silicon oxide, lanthanum oxide, yttrium oxide, or a combination thereof.

In some example embodiments, the first dielectric layer 146_1 may have a laminate structure including a first sub-dielectric layer and a second sub-dielectric layer, the first sub-dielectric layer may include zirconium oxide having a tetragonal crystalline phase, and the second sub-dielectric layer may include at least one of hafnium oxide, titanium oxide, strontium titanium oxide, hafnium zirconium oxide, niobium oxide, tantalum oxide, aluminum oxide, silicon oxide, lanthanum oxide, or yttrium oxide.

The first plate electrode 140_1 may be the first storage node electrode of the first memory unit ME1, the first electrode 144_1 may be the second storage node electrode of the first memory unit ME1, and the first dielectric layer 146_1 disposed between the first plate electrode 140_1 and the first electrode 144_1 may correspond to a capacitor dielectric layer. Accordingly, the first plate electrode 140_1, the first electrode 144_1, and the first dielectric layer 146_1 disposed therebetween may form a first capacitor of volatile memory. The first plate electrode 140_1, the first electrode 144_1, and the first dielectric layer 146_1 disposed therebetween may correspond to the first memory unit ME1 of FIG. 6.

In some example embodiments, as illustrated in FIG. 9, the plurality of openings 140H penetrating one first plate electrode 140_1 may be apart from each other in the first horizontal direction (the X direction), and the plurality of common electrodes 150, the plurality of first electrodes 144_1, and the plurality of first dielectric layers 146_1 may be disposed in each of the plurality of openings 140H. Accordingly, the plurality of first memory units ME1 arranged on the same vertical level (e.g., the second vertical level LV2) and apart from each other in the first horizontal direction (the X direction) may share one first plate electrode 140_1.

In some example embodiments, as illustrated in FIG. 9, one first plate electrode 140_1 may have a bar shape extending in the first horizontal direction (the X direction) and a stack separation insulating layer 152 may be disposed between two adjacent first plate electrodes 140_1 in the second horizontal direction (the Y direction). Accordingly, the plurality of common electrodes 150 apart from each other in the first horizontal direction (the X direction) may be surrounded by one first plate electrode 140_1 and the plurality of common electrodes 150 apart from each other in the second horizontal direction (the Y direction) may each be surrounded by an individual first plate electrode 140_1.

In some example embodiments, a second electrode 144_2 and a second dielectric layer 146_2 surrounding the side wall of the common electrode 150 may be disposed in each opening 140H of the plurality of second plate electrodes 140_2. In some example embodiments, the second electrode 144_2 and the second dielectric layer 146_2 may each have an annular form surrounding the common electrode 150. The second electrode 144_2 and the second dielectric layer 146_2 may be disposed between each of the plurality of second plate electrodes 140_2 and the common electrode 150.

In some example embodiments, a plurality of second electrodes 144_2 may be apart from each other in the vertical direction (the Z direction) on the side wall of the common electrode 150 extending in the vertical direction (the Z direction), and the plurality of second dielectric layers 146_2 may be apart from each other in the vertical direction (the Z direction) on the side wall of each of the plurality of second electrodes 144_2. As illustrated in FIG. 8, upper surfaces of the second plate electrode 140_2, the second dielectric layer 146_2, and the second electrode 144_2 may be arranged on the same plane, and bottom surfaces of the second plate electrode 140_2, the second dielectric layer 146_2, and the second electrode 144_2 may be arranged on the same plane.

In some example embodiments, the stack insulating layer 142 may be disposed on an upper surface and a bottom surface of each of the plurality of second electrodes 144_2, and the stack insulating layer 142 may be disposed on an upper surface and a bottom surface of each of the plurality of second dielectric layers 146_2.

In some example embodiments, the plurality of second electrodes 144_2 and the plurality of first electrodes 144_1 may be alternately disposed on the side wall of one common electrode 150 extending in the vertical direction (the Z direction). For example, the first electrode 144_1 may be disposed on the second vertical level LV2 and the second electrode 144_2 adjacent to the first electrode 144_1 may be disposed on the third vertical level LV3 higher than the second vertical level LV2. The plurality of second electrodes 144_2 may vertically overlap the plurality of first electrodes 144_1, respectively, and the plurality of second dielectric layers 146_2 may vertically overlap the plurality of first dielectric layers 146_1, respectively.

In some example embodiments, the second electrode 144_2 may include at least one of Si, SiGe, Ti, TiN, Ta, TaN, W, WN, TiSiN, WSiN, Ru, Mo, or MoN. In some example embodiments, the second dielectric layer 146_2 may include a ferroelectric material or an antiferroelectric material. In some example embodiments, the second dielectric layer 146_2 may include zirconium oxide, hafnium oxide, titanium oxide, hafnium zirconium oxide, niobium oxide, tantalum oxide, aluminum oxide, silicon oxide, lanthanum oxide, barium oxide, indium oxide, yttrium oxide, or a combination thereof.

In some example embodiments, the second dielectric layer 146_2 may have a laminate structure including a third sub-dielectric layer and a fourth sub-dielectric layer, the third sub-dielectric layer may include zirconium oxide having an orthorhombic crystalline phase, and the fourth sub-dielectric layer may include at least one of zirconium oxide, hafnium oxide, titanium oxide, hafnium zirconium oxide, niobium oxide, tantalum oxide, aluminum oxide, silicon oxide, lanthanum oxide, barium oxide, indium oxide, or yttrium oxide.

The second plate electrode 140_2 may be the first storage node electrode of the second memory unit ME2, the second electrode 144_2 may be a second storage node electrode of the second memory unit ME2, and the second dielectric layer 146_2 disposed between the second plate electrode 140_2 and the second electrode 144_2 may correspond to a ferroelectric capacitor dielectric layer. Accordingly, the second plate electrode 140_2, the second electrode 144_2, and the second dielectric layer 146_2 disposed therebetween may form a second capacitor of non-volatile memory. The second plate electrode 140_2, the second electrode 144_2, and the second dielectric layer 146_2 disposed therebetween may correspond to the second memory unit ME2 of FIG. 6.

In some example embodiments, as illustrated in FIG. 10, the plurality of openings 140H penetrating one second plate electrode 140_2 may be apart from each other in the first horizontal direction (the X direction), and the plurality of common electrodes 150, the plurality of second electrodes 144_2, and the plurality of second dielectric layers 146_2 may be disposed in each of the plurality of openings 140H. Accordingly, the plurality of second memory units ME2 arranged on the same vertical level (e.g., the third vertical level LV3) and apart from each other in the first horizontal direction (the X direction) may share one second plate electrode 140_2.

As illustrated in FIGS. 5 and 7, a connection stack CON may be disposed on one side of the memory cell stack MST. The connecting stack CON may include an electrode extension 140P extending from each of the plurality of plate electrodes 140. The electrode extensions 140P may have a step shape in which the height of each of the electrode extension 140P decreases along the first horizontal direction (the X direction).

In some example embodiments, a cell contact CP may be disposed on the electrode extension 140P. For example, a first cell contact CP1 may be disposed on the electrode extension 140P electrically connected to the first plate electrode 140_1 and a second cell contact CP2 may be disposed on the electrode extension 140P electrically connected to the second plate electrode 140_2.

In some example embodiments, the transistor region 120R may be formed on the substrate 110, the memory cell stack MST may be formed on the transistor region 120R, and the common electrode 150 may penetrate the memory cell stack MST and be electrically connected to the second contact 134 of the transistor region 120R (or the wiring layer 133 electrically connected to the second contact 134). In this case, the common electrode 150 may be directly connected to the second contact 134.

In some example embodiments, the transistor region 120R may be formed on the substrate 110, the memory cell stack MST and the common electrode 150 penetrating the memory cell stack MST may be formed on an additional substrate, and then the substrate 110 and the additional substrate may be bonded together such that the transistor region 120R and the memory cell stack MST contact each other. In this case, the common electrode 150 may be electrically connected to the transistor region 120R through the bonding pad.

In FIGS. 5 to 10, an example embodiment is described in which the first transistor PTR1 and the second transistor PTR2 are disposed in the transistor region 120R disposed on the substrate 110, and the first transistor PTR1 and the second transistor PTR2 are electrically connected to one memory string MS. However, in some example embodiments, only the first transistor PTR1 may be disposed in the transistor region 120R disposed on the substrate 110 and the first transistor PTR1 may be electrically connected to one memory string MS. According to such example embodiments, a structure corresponding to the memory device 10B described with reference to FIG. 3 may be implemented.

In some example embodiments, only the first transistor PTR1 may be disposed in the transistor region 120R disposed on the substrate 110, an additional transistor region may be disposed on a higher level than the memory cell stack MST, and a second transistor may be disposed in the additional transistor region. Accordingly, the first transistor PTR1 and the second transistor may be electrically connected to both ends of the memory string MS, respectively. According to such example embodiments, a structure corresponding to the memory device 10A described with reference to FIG. 2 may be implemented.

According to the example embodiments described above, a memory device 100 may include memory strings MS, each of which includes the first memory unit ME1 including a volatile memory unit and the second memory unit ME2 including a non-volatile memory unit and connected to the fist memory unit ME1 through one common electrode 150. In an electronic device including such memory device 100, the memory device 100 may operate to store and read data as a volatile memory device or a non-volatile memory device in various memory devices such as an embedded chip or a neuromorphic chip. Therefore, the memory device 100 may have improved operational flexibility.

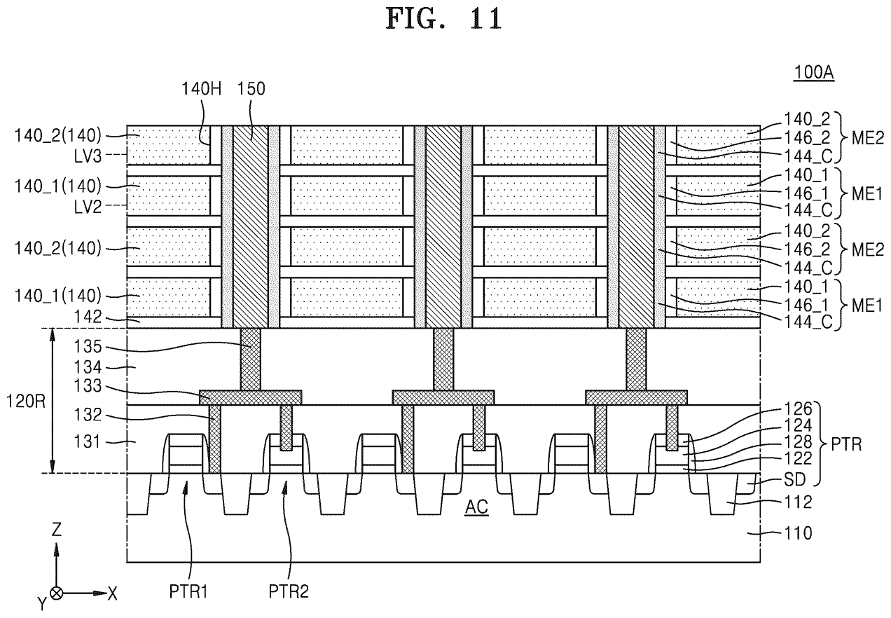

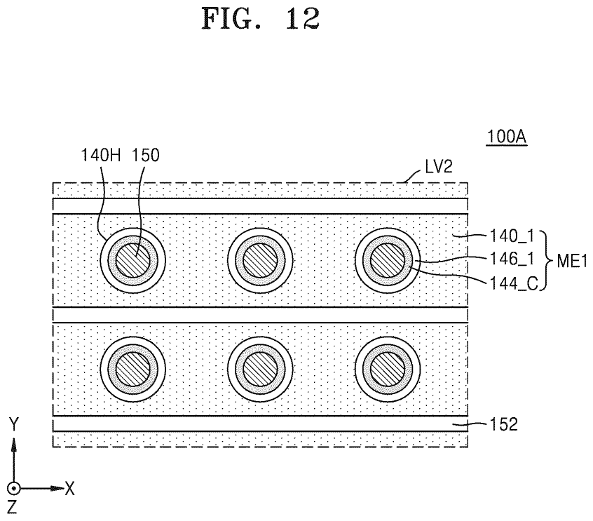

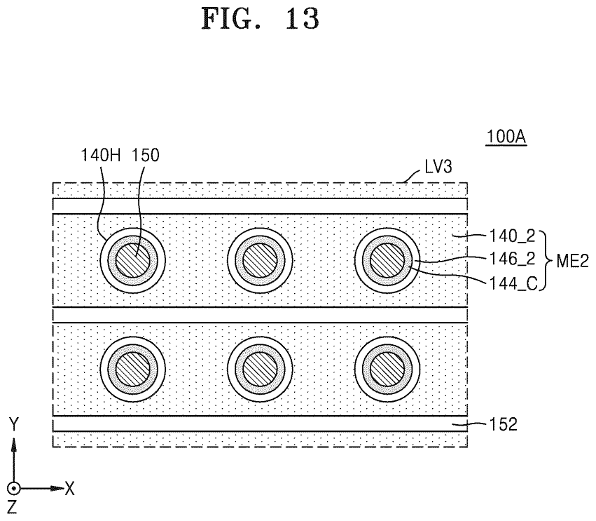

FIG. 11 is a cross-sectional view of a memory device 100A according to some example embodiments. FIG. 12 is a horizontal cross-sectional view of the memory device of FIG. 11 on the second vertical level LV2. FIG. 13 is a horizontal cross-sectional view of the memory device of FIG. 11 on the third vertical level LV3.

Referring to FIGS. 11 to 13, a common storage node 144_C may surround the common electrode 150 and extend in the vertical direction (the Z direction). In a plan view, the common storage node 144_C may surround the common electrode 150. The common storage node 144_C may have a cylindrical shape in which the top and the bottom are open.

The plurality of first dielectric layers 146_1 and the plurality of second dielectric layers 146_2 may be disposed alternately on the side wall of the common storage node 144_C and apart from each other in the vertical direction (the Z direction).

In some example embodiments, the first plate electrode 140_1 may be the first storage node electrode of the first memory unit ME1, the common storage node 144_C may be the second storage node electrode of the first memory unit ME1, and the first dielectric layer 146_1 disposed between the first plate electrode 140_1 and the common storage node 144_C may correspond to a capacitor dielectric layer. Accordingly, the first dielectric layer 146_1, a portion of the first plate electrode 140_1 disposed on both sides of the first dielectric layer 146_1, and a portion of the common storage node 144_C may constitute the first capacitor of the volatile memory and may correspond to the first memory unit ME1 illustrated in FIG. 6.

In some example embodiments, the second plate electrode 140_2 may be the first storage node electrode of the second memory unit ME2, the common storage node 144_C may be the second storage node electrode of the second memory unit ME1, and the second dielectric layer 146_2 disposed between the second plate electrode 140_2 and the common storage node 144_C may correspond to the capacitor dielectric layer. Accordingly, the second dielectric layer 146_2, a portion of the first plate electrode 140_1 disposed on both sides of the second dielectric layer 146_2, and a portion of the common storage node 144_C may constitute a second capacitor of the non-volatile memory and may correspond to the second memory unit ME2 illustrated in FIG. 6.

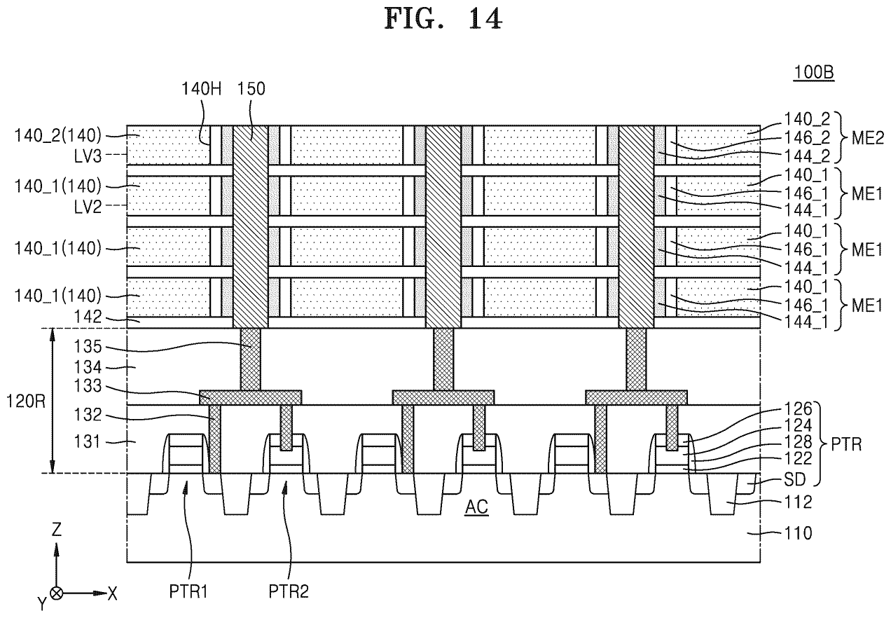

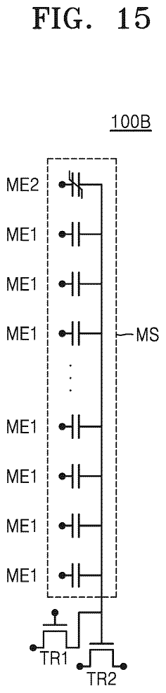

FIG. 14 is a cross-sectional view of a memory device 100B according to some example embodiments. FIG. 15 is a circuit diagram corresponding to the memory device 100B of FIG. 14.

Referring to FIGS. 14 and 15, the memory string MS may include at least one second memory unit ME2 disposed on the top of the memory string MS and the plurality of first memory units ME1 disposed on a vertical level lower than the at least one second memory unit ME2.

In some example embodiments, at least one second memory unit ME2 may surround a first portion of a side wall of the common electrode 150, and the plurality of first memory units ME1 may be apart from each other in the vertical direction (the Z direction) to surround a second portion of a side wall of the common electrode 150. In some example embodiments, the plurality of first electrodes 144_1 may be apart from each other in the vertical direction (the Z direction) on the side wall of the common electrode 150, and the plurality of first dielectric layers 146_1 may be apart from each other in the vertical direction (the Z direction) on the side wall of the common electrode 150.

In some example embodiments, the stack insulating layer 142 may be disposed between two adjacent first electrodes 144_1 among the plurality of first electrodes 144_1, and the stack insulating layer 142 may be disposed between two adjacent first dielectric layers 146_1 among the plurality of first dielectric layers 146_1.

In some example embodiments, the upper surface of each first dielectric layer 146_1 may be disposed on the same plane as the upper surface of the first electrode 144_1 and the upper surface of the first plate electrode 140_1. In some example embodiments, the bottom surface of each first dielectric layer 146_1 may be disposed on the same plane as the bottom surface of the first electrode 144_1 and the bottom surface of the first plate electrode 140_1.

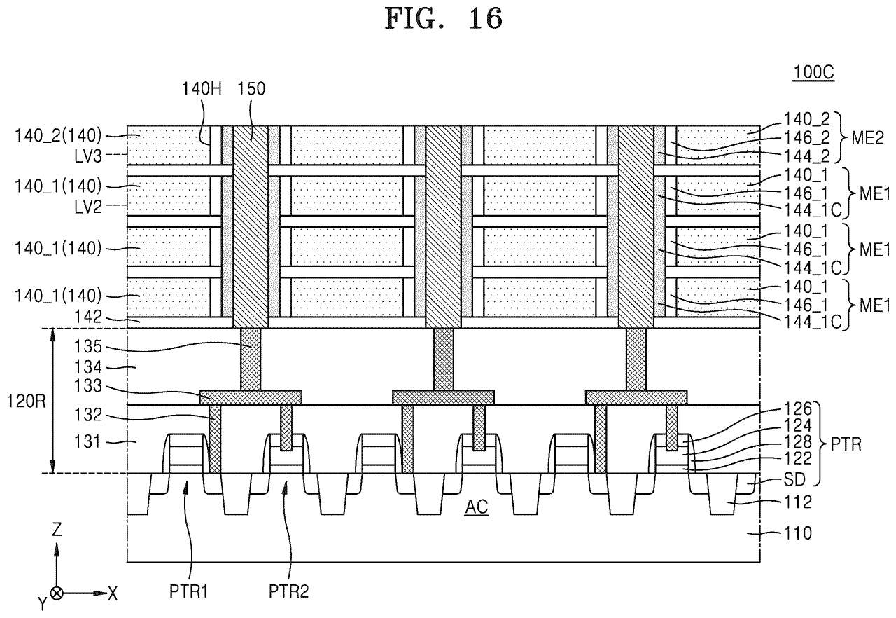

FIG. 16 is a cross-sectional view of a memory device 100C according to some example embodiments.

Referring to FIG. 16, the plurality of first memory units ME1 may include a common first electrode 144_1C. The common first electrode 144_1C may surround the common electrode 150 and extend in the vertical direction (the Z direction) and may be apart in the vertical direction (the Z direction) from the second electrode 144_2 included in at least one second memory unit ME2.

In some example embodiments, the first plate electrode 140_1 may be the first storage node electrode of the first memory unit ME1, the common first electrode 144_1C may be the second storage node electrode of the first memory unit ME1, and the first dielectric layer 146_1 disposed between the first plate electrode 140_1 and the common storage node 144_1C may correspond to the capacitor dielectric layer. Accordingly, the first dielectric layer 146_1, a portion of the first plate electrode 140_1 disposed on both sides of the first dielectric layer 146_1, and a portion of the common first electrode 144_1C may form the first capacitor of the volatile memory.

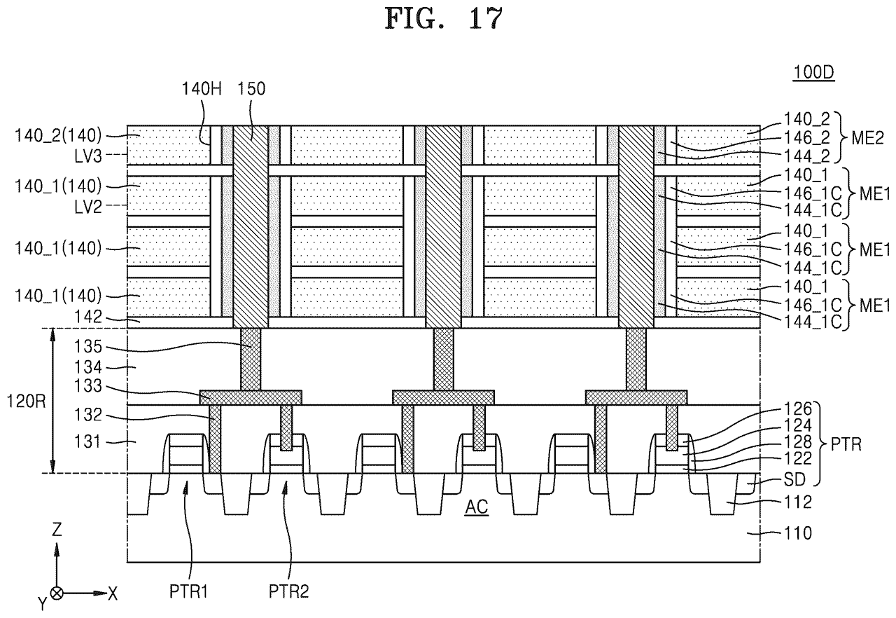

FIG. 17 is a cross-sectional view of a memory device 100d according to some example embodiments.

Referring to FIG. 17, the plurality of first memory units ME1 may include the common first electrode 144_1C and a common first dielectric layer 146_1C. The common first electrode 144_1C may surround the common electrode 150, extend in the vertical direction (the Z direction), and may be apart in the vertical direction (the Z direction) from the second electrode 144_2 included in at least one second memory unit ME2. The common first dielectric layer 146_1C may surround the common electrode 150 and the common first electrode 144_1C, extend in the vertical direction (the Z direction), and may be apart in the vertical direction (the Z direction) from the second dielectric layer 146_2 included in at least one second memory unit ME2.

The memory device according to an example embodiment may include the volatile memory unit disposed on the first vertical level and the non-volatile memory unit disposed on the second vertical level. Accordingly, a hybrid-type memory device capable of operating a volatile memory unit and a non-volatile memory unit may be implemented. The memory device may have improved operational flexibility that may be applied to various applications.

As described above, some example embodiments are disclosed in the drawings and the specification. Although the example embodiments were described using certain terms herein, the descriptions regarding the example embodiments should be considered in an illustrative sense only, and do not limit the meaning or scope of the inventive concepts as set forth in the claims.

While the inventive concepts have been particularly shown and described with reference to some example embodiments thereof, it will be understood that various changes in form and details may be made therein without departing from the spirit and scope of the following claims.

What is claimed is:

1. A memory device comprising:
a first transistor on a first vertical level on a substrate;
a common electrode electrically connected to the first transistor, the common electrode extending in a first direction perpendicular to an upper surface of the substrate;
a first memory unit on a second vertical level higher than the first vertical level on the substrate, the first memory unit electrically connected to the common electrode; and
a second memory unit on a third vertical level higher than the first vertical level and different from the second vertical level on the substrate, the second memory unit electrically connected to the common electrode, wherein
the first memory unit comprises a first dielectric layer including a dielectric material or a paraelectric material, and
the second memory unit comprises a second dielectric layer including a ferroelectric material or an antiferroelectric material.

2. The memory device of claim 1, wherein
the first memory unit comprises volatile memory, and
the second memory unit comprises non-volatile memory.

3. The memory device of claim 1, wherein
the common electrode is electrically connected to a drain region of the first transistor, and
the first transistor comprises a control transistor configured to control the first memory unit or the second memory unit.

4. The memory device of claim 1, further comprising
a second transistor on the first vertical level on the substrate, a gate electrode of the second transistor electrically connected to the common electrode, and
the second transistor comprises a sensing transistor configured to sense data stored in the first memory unit and the second memory unit.

5. The memory device of claim 1, wherein
the first memory unit comprises
a first electrode on a first portion of a side wall of the common electrode,
the first dielectric layer on a side wall of the first electrode, and
a first plate electrode on a side wall of the first dielectric layer, and the second memory unit comprises
a second electrode on a second portion of the side wall of the common electrode,
the second dielectric layer on a side wall of the second electrode, and
a second plate electrode on a side wall of the second dielectric layer.

6. The memory device of claim 5, wherein,
in a plan view, the first electrode has an annular shape surrounding the common electrode, and,
in a plan view, the first dielectric layer has an annular shape surrounding the first electrode.

7. The memory device of claim 5, wherein
the second dielectric layer vertically overlaps the first dielectric layer, and
the second electrode vertically overlaps the first electrode.

8. The memory device of claim 5, further comprising:
a first cell contact on an end of the first plate electrode, the first cell contact electrically connected to the first plate electrode; and
a second cell contact disposed on an end of the second plate electrode, the second cell contact electrically connected to the second plate electrode.

9. The memory device of claim 1, wherein
the first memory unit comprises a plurality of first memory units,
the second memory unit comprises a plurality of second memory units, and
the plurality of first memory units and the plurality of second memory units alternate in the first direction.

10. The memory device of claim 1, wherein
the first memory unit comprises a plurality of first memory units,
the second memory unit comprises a plurality of second memory units, and
a number of the plurality of first memory units is equal to or different from a number of the plurality of second memory units.

11. A memory device comprising:
a first transistor and a second transistor on a substrate;
a memory string electrically connected to the first transistor and the second transistor, the memory string being in a first direction perpendicular to an upper surface of the substrate, the memory string including a plurality of first memory units and a plurality of second memory units that are connected to each other in series; and
a common electrode extending in the first direction, the common electrode electrically connected to the first transistor and the second transistor, wherein
the plurality of first memory units comprise volatile memory and the plurality of second memory units comprise non-volatile memory.

12. The memory device of claim 11, wherein the plurality of first memory units and the plurality of second memory units alternate in the first direction.

13. The memory device of claim 12, wherein the plurality of first memory units and the plurality of second memory units surround the common electrode and are apart from each other in the first direction.

14. The memory device of claim 12, wherein,
among the plurality of first memory units, a first memory unit comprises
a first electrode surrounding the common electrode on a first vertical level,
a first dielectric layer on a side wall of the first electrode, and
a first plate electrode on a side wall of the first dielectric layer, and among the plurality of second memory units, a second memory unit comprises
a second electrode surrounding the common electrode on a second vertical level different from the first vertical level,
a second dielectric layer on a side wall of the second electrode, and
a second plate electrode on a side wall of the second dielectric layer.

15. The memory device of claim 14, wherein
the first dielectric layer comprises a dielectric material or a paraelectric material, and
the second dielectric layer comprises a ferroelectric material or an antiferroelectric material.

16. The memory device of claim 14, wherein the second electrode vertically overlaps the first electrode.

17. The memory device of claim 14, wherein the second plate electrode vertically overlaps the first plate electrode.

18. The memory device of claim 14, further comprising:
a first cell contact on an end of the first plate electrode, the first cell contact electrically connected to the first plate electrode; and
a second cell contact on an end of the second plate electrode, the second cell contact electrically connected to the second plate electrode.

19. A memory device comprising:
a plurality of first transistors on a first vertical level on a substrate;
a plurality of common electrodes electrically connected to the plurality of first transistors, respectively, the plurality of common electrodes extending in a first direction perpendicular to an upper surface of the substrate;
a first plate electrode on a second vertical level higher than the first vertical level on the substrate, the first plate electrode surrounding the plurality of common electrodes;
a plurality of first dielectric layers between the first plate electrode and the plurality of common electrodes, the plurality of first dielectric layers surrounding the plurality of common electrodes, respectively;
a second plate electrode on a third vertical level higher than the first vertical level and different from the second vertical level on the substrate, the second plate electrode surrounding the plurality of common electrodes; and
a plurality of second dielectric layers between the first plate electrode and the plurality of common electrodes, the plurality of second dielectric layers surrounding the plurality of common electrodes, respectively, wherein
the plurality of first dielectric layers comprise a dielectric material or a paraelectric material, and
the plurality of second dielectric layers comprise a ferroelectric material or an antiferroelectric material.

20. The memory device of claim 19, further comprising:
a plurality of first electrodes between each of the plurality of first dielectric layers and the plurality of common electrodes on the second vertical level; and
a plurality of second electrodes between each of the plurality of second dielectric layers and the plurality of common electrodes on the second vertical level.
